(19) United States
(12) Patent Application Publication
(10) Pub. No.: US 2026/0266934 A1
(43) Pub. Date: Sep. 10, 2026

(54) SYSTEM AND METHOD FOR MODULAR INSTALLATION OF LOOPS OF A RADIO FREQUENCY COIL

(71) Applicant: GE Precision Healthcare LLC, Waukesha, WI (US)

(72) Inventors: Edward Jospeh Baus, Akron, OH (US); Jana Michelle Vincent, Aurora, OH (US); Canyon Conner Aspy, Seven Hills, OH (US)

(21) Appl. No.: 19/072,024

(22) Filed: Mar. 6, 2025

(51) Int. Cl. G01R 33/34

(52) U.S. Cl. CPC G01R 33/34007; G01R 33/34084; G01R 33/34092

(57) ABSTRACT

A radio frequency (RF) receiving coil assembly for a magnetic resonance imaging (MRI) system includes a flexible enclosure. The radio frequency receiving coil assembly also includes a radio frequency coil disposed within the flexible enclosure. The radio frequency coil includes a plurality of flexible loops having a malleable conductor. Each flexible loop of the plurality of flexible loops is fastened to a material substrate layer disposed within the flexible enclosure via a modular assembly including a holding structure disposed over a respective flexible loop and one or more mechanical fasteners attaching both the holding structure and the respective flexible loop to the material substrate layer.

### BACKGROUND

The subject matter disclosed herein relates to medical imaging and, more particularly, to a system and method for modular installation of loops of a radio frequency (RF) coil for a magnetic resonance imaging (MRI) system.

Non-invasive imaging technologies allow images of the internal structures or features of a patient/object to be obtained without performing an invasive procedure on the patient/object. In particular, such non-invasive imaging technologies rely on various physical principles (such as the differential transmission of X-rays through a target volume, the reflection of acoustic waves within the volume, the paramagnetic properties of different tissues and materials within the volume, the breakdown of targeted radionuclides within the body, and so forth) to acquire data and to construct images or otherwise represent the observed internal features of the patient/object.

During magnetic resonance imaging, when a substance such as human tissue is subjected to a uniform magnetic field (polarizing field B₀), the individual magnetic moments of the spins in the tissue attempt to align with this polarizing field, but precess about it in random order at their characteristic Larmor frequency. If the substance, or tissue, is subjected to a magnetic field (excitation field B₁) which is in the x-y plane and which is near the Larmor frequency, the net aligned moment, or “longitudinal magnetization”, M_{z}, may be rotated, or “tipped”, into the x-y plane to produce a net transverse magnetic moment, Mₜ. A signal is emitted by the excited spins after the excitation signal B₁ is terminated and this signal may be received and processed to form an image.

When utilizing these signals to produce images, magnetic field gradients (Gₓ, G_{y}, and G_{z}) are employed. Typically, the region to be imaged is scanned by a sequence of measurement cycles in which these gradient fields vary according to the particular localization method being used. The resulting set of received nuclear magnetic resonance (NMR) signals are digitized and processed to reconstruct the image using one of many well-known reconstruction techniques.

Current techniques or mechanisms for assembling an RF coil involves sewing of the loops or elements of the RF coil onto a fabric substrate. Attaching these loops is difficult and time consuming. There is also a risk of damaging the loop or element which would require replacement. This requires an extensive amount of time and effort to carefully remove the damaged loop or element, replace it, and sew it back into position.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, a radio frequency (RF) receiving coil assembly for a magnetic resonance imaging (MRI) system is provided. The radio frequency receiving coil assembly includes a flexible enclosure. The radio frequency receiving coil assembly also includes a radio frequency coil disposed within the flexible enclosure. The radio frequency coil includes a plurality of flexible loops having a malleable conductor. Each flexible loop of the plurality of flexible loops is fastened to a material substrate layer disposed within the flexible enclosure via a modular assembly including a holding structure holding a respective flexible loop and one or more mechanical fasteners attaching both the holding structure and the respective flexible loop to the material substrate layer.

In another embodiment, a modular assembly for assembling a radio frequency receiving coil assembly for a magnetic imaging system is provided. The modular assembly includes a holding structure configured to hold a flexible loop of the radio frequency receiving coil assembly, wherein the flexible loop has a malleable conductor. The modular assembly also includes an electronics unit coupled to the holding structure;. The modular assembly further includes mechanical fasteners configured to attach the electronics unit, the holding structure, and the flexible loop to a material substrate layer configured to be disposed within a flexible enclosure. The holding structure is configured to maintain a position of the flexible loop on the material substrate layer as the one or more mechanical fasteners is fastened to the holding structure to attach both the holding structure and the respective loop to the material substrate layer.

In a further embodiment, a method for modular assembly and repair of a radio frequency coil for a magnetic imaging system. The method includes providing a material substrate layer. The method also includes placing a modular assembly comprising a holding structure holding a flexible loop of the radio frequency coil, wherein the flexible loop has a malleable conductor. The method further includes aligning the holding structure and the flexible loop to a position on the material substrate layer. The method further includes fastening the holding structure and the flexible loop to the material substrate layer.

### BRIEF DESCRIPTION OF THE DRAWINGS

These and other features, aspects, and advantages of the present subject matter will become better understood when the following detailed description is read with reference to the accompanying drawings in which like characters represent like parts throughout the drawings, wherein:

FIG. 1 illustrates an embodiment of a magnetic resonance imaging (MRI) system suitable for use with the disclosed technique;

FIG. 2 is a schematic diagram of a radio frequency (RF) coil assembly having a layered and/or dual-sided arrangement for coil elements, in accordance with aspects of the present disclosure;

FIG. 3 is a schematic diagram of a cross-section of a coil element, in accordance with aspects of the present disclosure;

FIG. 4 is a schematic diagram of a modular assembly for mechanical attachment of a flexible loop or element of a radio frequency coil assembly, in accordance with aspects of the present disclosure;

FIG. 5 is a flow diagram of a method for modular assembly of a radio frequency coil assembly, in accordance with aspects of the present disclosure;

FIG. 6 is a flow diagram of a method for replacing a flexible loop or element of a radio frequency coil assembly, in accordance with aspects of the present disclosure;

FIG. 7 is a schematic diagram of a perspective view of a modular assembly coupled to a flexible loop of a radio frequency coil assembly, in accordance with aspects of the present disclosure;

FIG. 8 is a schematic diagram of a portion of a modular assembly coupled to a flexible loop of a radio frequency coil assembly, in accordance with aspects of the present disclosure;

FIG. 9 is a schematic diagram of a top view of modular assemblies respectively coupled to flexible loops of a radio frequency coil assembly, in accordance with aspects of the present disclosure;

FIG. 10 is a schematic diagram of a perspective view of the modular assemblies respectively coupled to flexible loops in FIG. 8, in accordance with aspects of the present disclosure;

FIG. 11 is a schematic diagram of a top view of a holding structure having a squiggly shape, in accordance with aspects of the present disclosure;

FIG. 12 is a schematic diagram of a top view of a smaller holding structure having a squiggly shape, in accordance with aspects of the present disclosure; and

FIG. 13 is a schematic diagram of a top view of the holding structures in FIGS. 11 and 12, in accordance with aspects of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers’ specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing coil elements of various embodiments of the present subject matter, the articles “a,” “an,” “the,” and “said” are intended to mean that there are one or more of the coil elements. The terms “comprising,” “including,” and “having” are intended to be inclusive and mean that there may be additional coil elements other than the listed coil elements. Furthermore, any numerical examples in the following discussion are intended to be non-limiting, and thus additional numerical values, ranges, and percentages are within the scope of the disclosed embodiments.

In the following, a mechanical fastener may be mechanical fasteners, screws, grommets, epoxy, press-fit connectors, snaps, buttons, eyelets, pin, or other types fasteners. In the following, the material substrate layer may be a fabric, a film, a solid plastic material, or other type of material.

The present disclosure provides a system and method for modular installation of loops (e.g., elements) of a radio frequency (RF) coil for a magnetic resonance imaging (MRI) system. In particular, the system and method provide for the mechanical attachment of the loops of the radio frequency coil to a material substrate layer (e.g., flexible anchoring material layer). It creates a modular design that can replace coil elements in an array by removing the mechanical fasteners that hold the loop in place. The disclosed embodiments eliminate the sewing of the coil elements and instead provides for the fastening of the loop and electronics onto the fabric directly. This allows for quicker replacement and assembly than the current techniques. A holding structure which holds the loop is attached via one or more mechanical fasteners (e.g., made of copper, plastic, or other material) to the substrate to retain the loop to the fabric substrate. The holding structure keeps the coil loop from folding over itself and not returning to a desired relaxed confirmation after deformation of array.

The disclosed embodiments provide a more reliable manufacturing method. The disclosed embodiments reduce cost and provide a more modular design. The disclosed embodiments reduce manufacturing time. The disclosed embodiments reduce the number of failures seen and improve repair times on the radio frequency receiving coil assembly.

The disclosed embodiments include a radio frequency (RF) receiving coil assembly for a magnetic resonance imaging (MRI) system is provided. The radio frequency receiving coil assembly includes a flexible enclosure. The radio frequency receiving coil assembly also includes a radio frequency coil disposed within the flexible enclosure. The radio frequency coil includes a plurality of flexible loops having a malleable conductor. Each flexible loop of the plurality of flexible loops is fastened to a material substrate layer disposed within the flexible enclosure via a modular assembly including a holding structure holding a respective flexible loop and one or more mechanical fasteners attaching both the holding structure and the respective flexible loop to the material substrate layer.

In certain embodiments, the holding structure is configured to maintain a position of the respective flexible loop on the material substrate layer as the one or more mechanical fasteners is fastened to the holding structure to attach both the holding structure and the respective flexible loop to the material substrate layer. In certain embodiments, the modular assembly further includes an electronics unit electronically coupled to the respective flexible loop and coupled to the holding structure that is fastened via one or more mechanical fasteners to the material substrate layer. In certain embodiments, the holding structure includes a hub and a plurality of spokes radially extending from the hub. In certain embodiments, respective ends of the plurality of spokes disposed away from the hub include receptacles for receiving the respective flexible loop and holding the respective flexible loop in the position on the material substrate layer prior to and subsequent to attachment to the material substrate layer. In certain embodiments, a mechanical method of attachment using one or more mechanical fasteners is fastened to the hub to attach both the holding structure and the respective flexible loop to the material substrate layer. In certain embodiments, the holding structure comprises one or more holes within it that are off center from a center of the holding structure, and the one or more mechanical fasteners are disposed within the holes to attach both the holding structure and the respective flexible loop to the material substrate layer. In certain embodiments, the modular assembly is configured to enable removal of the respective flexible loop for replacement via the removal of the one or more mechanical fasteners to detach the respective flexible loop from the material substrate layer.

The disclosed embodiments include a modular assembly for assembling a radio frequency receiving coil assembly for a magnetic imaging system is provided. The modular assembly includes a holding structure configured to hold a flexible loop of the radio frequency receiving coil assembly, wherein the flexible loop has a malleable conductor. The modular assembly also includes an electronics unit coupled to the holding structure. The modular assembly further includes mechanical fasteners configured to attach the electronics unit, the holding structure, and the flexible loop to a material substrate layer configured to be disposed within a flexible enclosure. The holding structure is configured to maintain a position of the flexible loop on the material substrate layer as the one or more mechanical fasteners is fastened to the holding structure to attach both the holding structure and the respective loop to the material substrate layer.

In certain embodiments, the holding structure includes a hub and a plurality of spokes radially extending from the hub. In certain embodiments, respective ends of the plurality of spokes disposed away from the hub include receptacles for receiving the flexible loop and holding the flexible loop in the position on the material substrate layer prior to and subsequent to attachment to the material substrate layer. In certain embodiments, a mechanical fastener of the one or more mechanical fasteners is fastened to the holding structure to attach both the holding structure and the flexible loop to the material substrate layer. In certain embodiments, the holding structure includes one or more holes within it that are off center from a center of the holding structure, and the one or more mechanical fasteners are disposed within the holes to attach both the holding structure and the flexible loop to the material substrate layer. In certain embodiments, the modular assembly is configured to enable removal of the flexible loop for replacement via the removal of the one or more mechanical fasteners to detach both the respective flexible loop and the electronics unit from the material substrate layer.

The disclosed embodiments include a method for modular assembly and repair of a radio frequency coil for a magnetic imaging system. The method includes providing a material substrate layer. The method also includes placing a modular assembly comprising a holding structure holding a flexible loop of the radio frequency coil on the material substrate layer, wherein the flexible loop has a malleable conductor. The method further includes aligning the holding structure and the flexible loop to a position on the material substrate layer. The method further includes fastening the holding structure and the flexible loop to the material substrate layer.

In certain embodiments, the holding structure is configured to maintain a position of the flexible loop on the material substrate layer as the one or more mechanical fasteners is fastened to the holding structure to attach both the holding structure and the flexible loop to the material substrate layer. In certain embodiments, the modular assembly includes an electronics unit electrically coupled to the flexible loop and coupled to the holding structure, wherein the method further comprises attaching the electronics unit to the material substrate layer via one or more additional mechanical fasteners. In certain embodiments, the method includes detaching the one or more mechanical fasteners and the one or more additional mechanical fasteners, removing the flexible loop associated with the modular assembly, coupling the modular assembly to a replacement flexible loop of the radio frequency coil, placing the modular assembly with the replacement flexible loop of the radio frequency coil on the material substrate layer, aligning the holding structure and the replacement flexible loop to the position on the material substrate layer, and fastening the electronics unit, the holding structure, and the replacement flexible loop to the material substrate layer. In certain embodiments, the method includes disposing the material substrate layer with the modular assembly and the flexible loop fastened to the material subject layer into a flexible enclosure. In certain embodiments, the holding structure comprises receptacles for receiving the flexible loop and holding the flexible loop in the position on the material substrate layer prior to and subsequent to attachment to the material substrate layer.

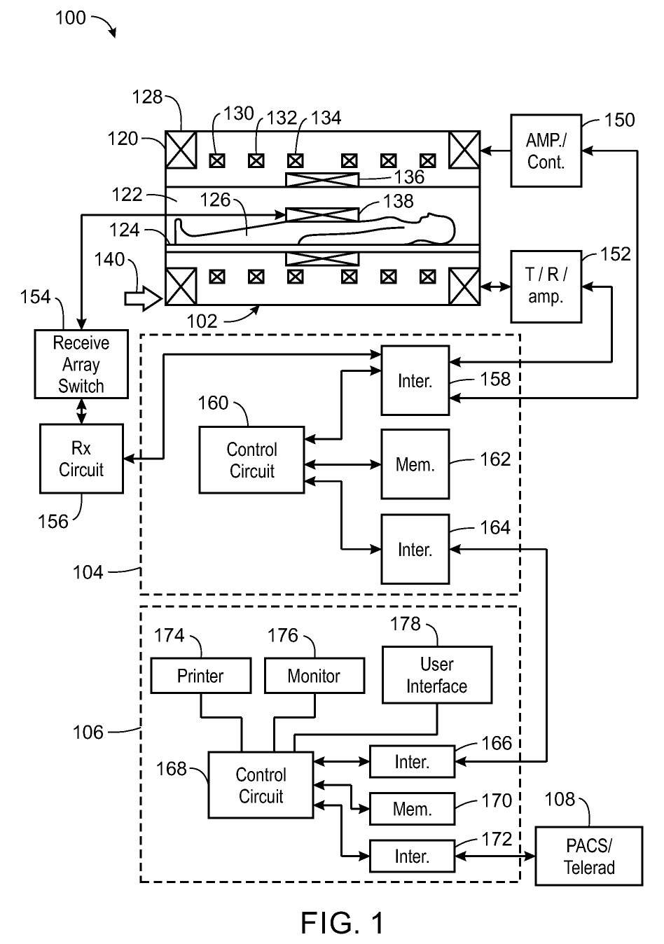

With the preceding in mind, FIG. 1 a magnetic resonance imaging (MRI) system 100 is illustrated schematically as including a scanner 102, scanner control circuitry 104, and system control circuitry 106. According to the embodiments described herein, the magnetic resonance imaging system 100 is generally configured to perform MR imaging.

System 100 additionally includes remote access and storage systems or devices such as picture archiving and communication systems (PACS) 108, or other devices such as teleradiology equipment so that data acquired by the system 100 may be accessed on- or off-site. In this way, MR data may be acquired, followed by on- or off-site processing and evaluation. While the magnetic resonance imaging system 100 may include any suitable scanner or detector, in the illustrated embodiment, the system 100 includes a full body scanner 102 having a housing 120 through which a bore 122 is formed. A table 124 is moveable into the bore 122 to permit a patient 126 to be positioned therein for imaging selected anatomy within the patient.

Scanner 102 includes a series of associated coils for producing controlled magnetic fields for exciting the gyromagnetic material within the anatomy of the subject being imaged. Specifically, a primary magnet coil 128 is provided for generating a primary magnetic field, B₀, which is generally aligned with the bore 122. A series of gradient coils 130, 132, and 134 permit controlled magnetic gradient fields to be generated for positional encoding of certain gyromagnetic nuclei within the patient 126 during examination sequences. A radio frequency (RF) coil 136 (e.g., radio frequency transmit coil) is configured to generate radio frequency pulses for exciting the certain gyromagnetic nuclei within the patient. In addition to the coils that may be local to the scanner 102, the system 100 also includes a set of receiving coils or radio frequency receiving coils 138 (e.g., an array of coils) configured for placement proximal (e.g., against) to the patient 126. As an example, the receiving coils 138 can include cervical/thoracic/lumbar (CTL) coils, head coils, single-sided spine coils, and so forth. Generally, the receiving coils 138 are placed close to or on top of the patient 126 so as to receive the weak radio frequency signals (weak relative to the transmitted pulses generated by the scanner coils) that are generated by certain gyromagnetic nuclei within the patient 126 as they return to their relaxed state.

The various coils of system 100 are controlled by external circuitry to generate the desired field and pulses, and to read emissions from the gyromagnetic material in a controlled manner. In the illustrated embodiment, a main power supply 140 provides power to the primary field coil 128 to generate the primary magnetic field, Bo. A power input (e.g., power from a utility or grid), a power distribution unit (PDU), a power supply (PS), and a driver circuit 150 may together provide power to pulse the gradient field coils 130, 132, and 134. The driver circuit 150 may include amplification and control circuitry for supplying current to the coils as defined by digitized pulse sequences output by the scanner control circuitry 104.

Another control circuit 152 is provided for regulating operation of the radio frequency coil 136. Circuit 152 includes a switching device for alternating between the active and inactive modes of operation, wherein the radio frequency coil 136 transmits and does not transmit signals, respectively. Circuit 152 also includes amplification circuitry configured to generate the radio frequency pulses. Similarly, the receiving coils 138 are connected to switch 154, which is capable of switching the receiving coils 138 between receiving and non-receiving modes. Thus, the receiving coils 138 resonate with the radio frequency signals produced by relaxing gyromagnetic nuclei from within the patient 126 while in the receiving mode, and they do not resonate with radio frequency energy from the transmitting coils (i.e., coil 136) so as to prevent undesirable operation while in the non-receiving mode. Additionally, a receiving circuit 156 is configured to receive the data detected by the receiving coils 138 and may include one or more multiplexing and/or amplification circuits.

It should be noted that while the scanner 102 and the control/amplification circuitry described above are illustrated as being coupled by a single line, many such lines may be present in an actual instantiation. For example, separate lines may be used for control, data communication, power transmission, and so on. Further, suitable hardware may be disposed along each type of line for the proper handling of the data and current/voltage. Indeed, various filters, digitizers, and processors may be disposed between the scanner and either or both of the scanner and system control circuitry 104, 106.

As illustrated, scanner control circuitry 104 includes an interface circuit 158, which outputs signals for driving the gradient field coils and the radio frequency coil and for receiving the data representative of the magnetic resonance signals produced in examination sequences. The interface circuit 158 is coupled to a control and analysis circuit 160. The control and analysis circuit 160 executes the commands for driving the circuit 150 and circuit 152 based on defined protocols selected via system control circuit 106.

Control and analysis circuit 160 also serves to receive the magnetic resonance signals and performs subsequent processing before transmitting the data to system control circuit 106. Scanner control circuit 104 also includes one or more memory circuits 162, which store configuration parameters, pulse sequence descriptions, examination results, and so forth, during operation.

Interface circuit 164 is coupled to the control and analysis circuit 160 for exchanging data between scanner control circuitry 104 and system control circuitry 106. In certain embodiments, the control and analysis circuit 160, while illustrated as a single unit, may include one or more hardware devices. The system control circuit 106 includes an interface circuit 166, which receives data from the scanner control circuitry 104 and transmits data and commands back to the scanner control circuitry 104. The control and analysis circuit 168 may include a CPU in a multi-purpose or application specific computer or workstation. Control and analysis circuit 168 is coupled to a memory circuit 170 to store programming code for operation of the magnetic resonance imaging system 100 and to store the processed image data for later reconstruction, display and transmission. The programming code may execute one or more algorithms that, when executed by a processor, are configured to perform reconstruction of acquired data as described below. In certain embodiments, the memory circuit 170 may store one or more neural networks for reconstruction of acquired data as described below. In certain embodiments, image reconstruction may occur on a separate computing device having processing circuitry and memory circuitry.

An additional interface circuit 172 may be provided for exchanging image data, configuration parameters, and so forth with external system components such as remote access and storage devices 108. Finally, the system control and analysis circuit 168 may be communicatively coupled to various peripheral devices for facilitating operator interface and for producing hard copies of the reconstructed images. In the illustrated embodiment, these peripherals include a printer 174, a monitor 176, and user interface 178 including devices such as a keyboard, a mouse, a touchscreen (e.g., integrated with the monitor 176), and so forth.

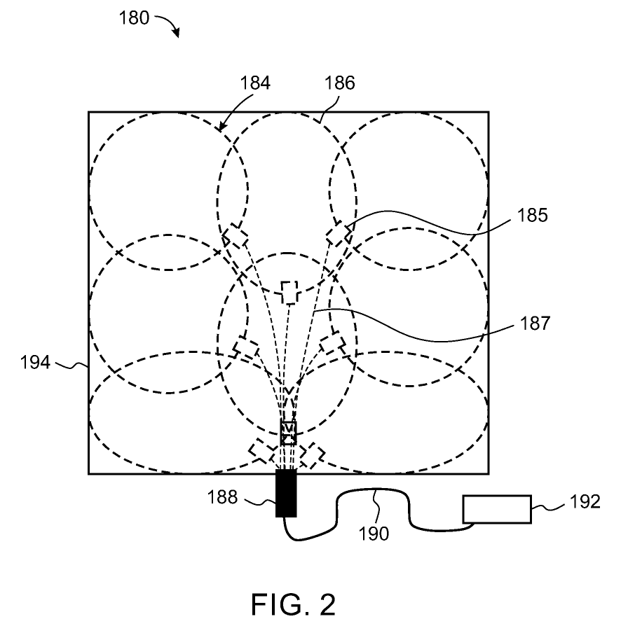

FIG. 2 is a schematic diagram of a radio frequency coil assembly 180 (e.g., radio frequency receiving coil assembly) having a layered and/or dual-sided arrangement for coil elements. The radio frequency coil assembly 180 may be utilized in a magnetic resonance imaging system (e.g., magnetic resonance imaging system 100 in FIG. 1). The radio frequency coil assembly 180 includes a radio frequency coil 184 having a plurality of coil elements 186 (e.g., flexible loops or channels). Each element 186 is coupled to an electronics unit 185 (e.g., feedboard) coupled to a coil-interfacing cable 187. The coil-interfacing cables 187 of each of the coil elements 186 is coupled to an electrical connector interface or interface circuitry 188 (e.g., a balun such as integrated balun cable harness which may act as a radio frequency trap). The electrical connector interface 188 is coupled (via a cable 190) to a P connector 192 (e.g., port connector) that enables the radio frequency coil assembly 180 to be coupled (e.g., via wired connection) to the interface of the magnetic resonance imaging system that couples imaging components to processing components. In certain embodiments, the radio frequency coil assembly 180 may lack a wired connection and may be configured to be utilized wirelessly (e.g., for coupling imaging components to wireless components) with the magnetic resonance imaging system during a magnetic resonance imaging scan.

Each element 186 may consist of linked resonator coil elements coupled to a printed circuit board module (e.g., the electronics unit 185). Each electronics unit 185 may include various components (e.g., a decoupling circuit, an impedance inverter circuit, and a pre-amplifier). The radio frequency coil 184 may be designed utilizing AIR™ coil technology from General Electric Healthcare. This enables the radio frequency coil 184 to be lightweight and flexible. Each element 186 includes a malleable (e.g., flexible) or conductor that enables complex and irregular surface contours. In certain embodiments, each element 186 may stretch (e.g., due to a liquid metal conductor, stretchable/elastic conductor, or meandering structure). In addition, the coil elements 186 of the radio frequency coil 184 are transparent, thus, aiding signal-to-noise ratios.

The radio frequency coil 184 is disposed within a flexible enclosure 194 (e.g., blanket). As depicted, the flexible enclosure 194 has a rectangular shape. In certain embodiments, the flexible enclosure 194 may have a square shape or other shape. In certain embodiments, the flexible enclosure 194 includes holes or openings to increase a flexibility of the radio frequency coil assembly 180 (and the flexible enclosure 194). Each hole or opening may be radially located within the element 186. In certain embodiments, the flexible enclosure 194 may include deformable material within. The deformable material may include foam, memory foam, expanded foam, polyurethane foam, gels such as hydrogel, cells of water, or other suitable deformable material. When the subject lies on the radio frequency coil assembly 180, the subject will sink into the deformable material and the radio frequency coil 184 may conform to the subject’s unique shape and, thus, be right up against the patient’s body. As depicted, the interface circuitry 188 is disposed within the flexible enclosure 194. In certain embodiments, the interface circuitry 188 may be disposed outside the flexible enclosure 194.

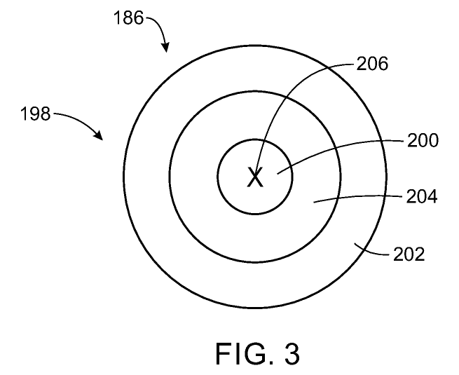

Each coil element 186 includes a distributed capacitance construction. In particular, each coil element 186 includes a coaxial conductor having a cross-section configured to generate exact capacitance for element tuning at a specific frequency. For example, as depicted in FIG. 3, a coaxial coil element portion 198 (of the coil element 186) includes a round center conductor wire 200, an outer concentric shield 202, and a dielectric material 204 in between. The center conductor wire 200 may be of copper (e.g., silver plated copper) and the dielectric material 204 may be rubber, plastic, or some other dielectric material (e.g., fluoroethylenepropylene (FEP) or polytetrafluoroethylene (pTFE)). The outer concentric shield 202 may encase or otherwise surround the dielectric material 204 and center conductor wire 200 and may be comprised of braided copper or other suitable conductive material. The center conductor 200, dielectric material 204, and outer shield 202 all share a common central axis 206. Further, while not shown in FIG. 3, in some examples, an outer jacket (e.g., made of dielectric material) may surround the outer shield 202. While two coaxial conductors (center conductor wire 200 and outer shield 202) are shown in FIG. 3, a radio frequency coil element portion may include three or more coaxial conductors, encapsulated and separated from each other by dielectric material. In certain embodiments, the center conductor wire 200 may be made of a liquid metal conductor to enable the coil element 186 to be stretched.

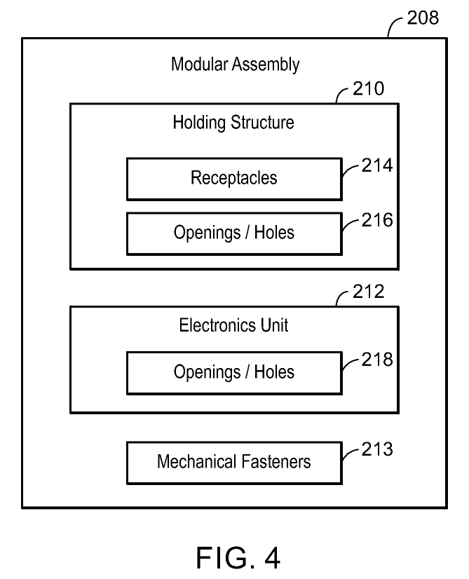

FIG. 4 is a schematic diagram of a modular assembly 208 for mechanical attachment of flexible a loop or element (e.g., coil element 186 in FIG. 2) of a radio frequency coil assembly (e.g., radio frequency coil assembly 180 in FIG. 2). The modular assembly 208 includes a holding structure 210 (e.g., retaining structure) and an electronic unit 212 (e.g., electronic unit 185 in FIG. 2). The holding structure 210 is made of MRI compatible material (e.g., non-magnetic metals, polymers, or plastics). The modular assembly 208 also includes mechanical fasteners 213 (e.g., copper, plastic, or other conductive material) for attaching both the holding structure 210 and the electronics unit 212 directly and the flexible loop (via the holding structure 210) indirectly to a material substrate layer (e.g., flexible anchoring material layer). The holding structure 210 is configured to hold a flexible loop while maintaining its looped shape. In particular, the holding structure 210 includes receptacles 214 for receiving the flexible loop and holding the flexible loop. In certain embodiments, the receptacles 214 are disposed on a periphery of the holding structure 210. The holding structure 210 is configured to maintain a position of the flexible loop on a material substrate layer (e.g., flexible anchoring material layer) as the one or more mechanical fasteners 213 is fastened to the holding structure 210 to attach both the holding structure 210 and the flexible loop to the material substrate layer. The holding structure 210 includes openings or holes 216 for receiving the mechanical fasteners 213 (e.g. during pressing) for attachment of the holding structure 210 to the material substrate layer.

The shape of the holding structure 210 may vary. The shape of the holding structure 210 may be any shape that maintains the shape of the flexible loop (e.g., a hoop). In certain embodiments, the holding structure 210 may be a transparent film. In certain embodiments, the holding structure 210 may include spokes coupled to and radially extending from a hub. In certain embodiments, the holding structure 210 may be fastened (e.g., via a hole or opening 216 in the hub) to the material substrate layer via the mechanical fastener213. In certain embodiments, holes or openings 216 may be disposed along one or more of the spokes for receiving mechanical fasteners for attachment of the holding structure 210 to the material substrate layer. In certain embodiments, the holding structure 210 is fastened to the material substrate layer (e.g., via one or more mechanical fasteners) at one or more openings or holes 216 within it that are off center from a center of the holding structure 210 via mechanical fasteners 213 are disposed within the holes 216 to attach both the holding structure 210 and the flexible loop to the material substrate layer. In certain embodiments, the modular assembly 208 includes multiple holding structures coupled together to enable fastening of multiple respective flexible loops (e.g., and the flexible loops may share a common electronics unit).

The electronics unit 212 is configured to electronically couple to the flexible loop (coupled to the holding structure 210). The electronics unit 212 is also coupled to the holding structure 210. The electronics unit 212 includes openings or holes 218 for receiving the mechanical fasteners 213 to fasten the electronics unit 212 to the material substrate layer. In certain embodiments, the electronics unit 212 may be coupled to the material substrate layer via a different means than the mechanical fasteners. In certain embodiments, the electronics unit 212 may be coupled to the material substrate layer via a different means than how the holding structure 210 is coupled to the material substrate layer. In certain embodiments, the electronics unit 212 may not be coupled to the holding structure 210 (but coupled to the material substrate layer remote from the material substrate layer.

The modular assembly 208 is configured to enable replacement of a flexible loop. Unfastening the mechanical fasteners 213, enables the modular assembly 208 to be removed from the material substrate layer, where the flexible loop can be replaced on the modular assembly 208. Then, the modular assembly 208 may be returned to its original position and reattached with the new flexible loop.

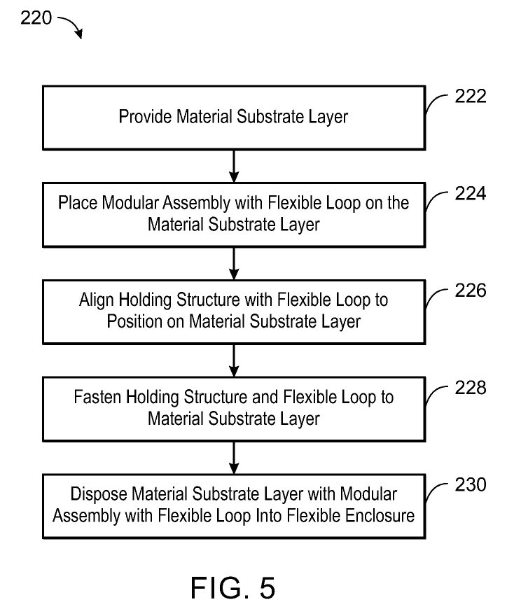

FIG. 5 is a flow diagram of a method 220 for modular assembly of a radio frequency coil assembly (e.g., radio frequency coil assembly 180 in FIG. 2). The method 220 utilizes the modular assemblies 208 in FIG. 2 for modular assembly of each of the flexible loops of the radio frequency coil assembly.

The method 220 includes providing a material substrate layer (block 222). The method 220 also includes placing a modular assembly including a holding structure holding a flexible loop of the radio frequency coil on the material substrate layer, wherein the flexible loop has a malleable conductor (block 224). The method 220 further includes aligning the holding structure and the flexible loop to a position on the material substrate layer (block 226). The method further includes fastening the holding structure and the flexible loop to the material substrate layer (block 228). The method 220 even further includes disposing the material substrate layer with the modular assembly and the flexible loop fastened to the material subject layer into a flexible enclosure (block 230).

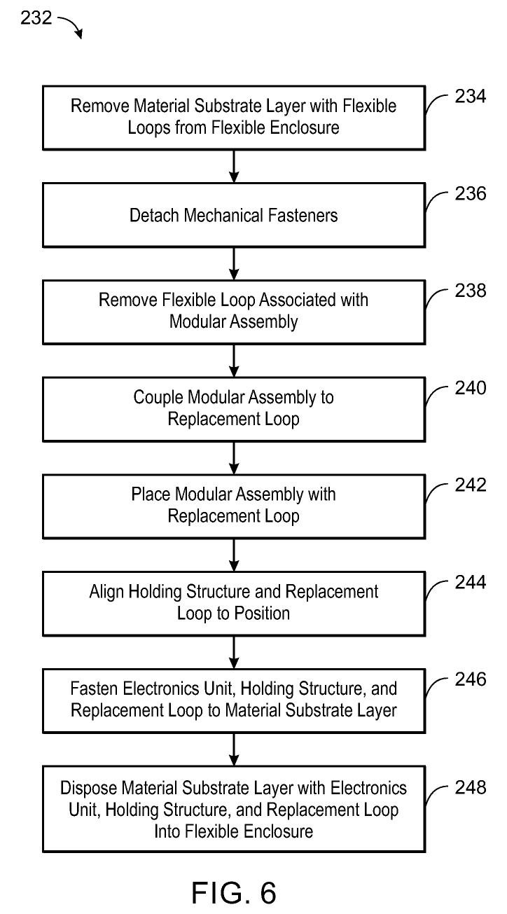

FIG. 6 is a flow diagram of a method 232 for replacing a flexible loop or element of a radio frequency coil assembly. The method 232 utilizes the modular assemblies 208 in FIG. 2 for modular assembly of each of the flexible loops of the radio frequency coil assembly.

The method 232 includes removing a material substrate layer with the flexible loops of the radio frequency coil assembly from a flexible enclosure (block 234). The method 232 also includes detaching the one or more mechanical fasteners (e.g., fastened to the holding structure) and the one or more additional mechanical fasteners (e.g., fastened to the electronics unit) (block 236). The method 232 also includes removing the flexible loop associated with the modular assembly (block 238). The method 232 further includes coupling the modular assembly to a replacement flexible loop of the radio frequency coil (block 240). The method 232 even further includes placing the modular assembly with the replacement flexible loop of the radio frequency coil on the material substrate layer (block 242). The method 232 further includes aligning the holding structure and the replacement flexible loop to the position on the material substrate layer (block 244). The method 232 includes fastening the electronics unit, the holding structure, and the replacement flexible loop to the material substrate layer (block 246). The method 232 even further includes disposing the material substrate layer with the electronics unit, the holding structure, and the replacement flexible loop fastened to the material subject layer into the flexible enclosure (block 248).

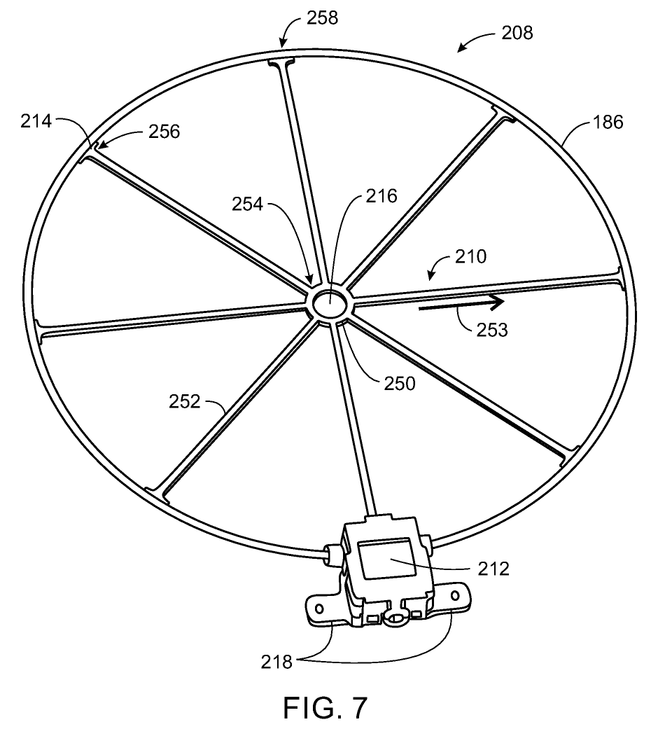

FIG. 7 is a schematic diagram of a perspective view of the modular assembly 208 coupled to the flexible loop 186 of a radio frequency coil assembly. The modular assembly 208 includes the holding structure 210 and the electronic unit 212. The holding structure 210 is made of an MRI compatible material (e.g., non-magnetic metals, polymers, or plastics). As depicted, the holding structure 210 includes a hub 250 (which is centrally located) and a plurality of spokes 252 extending radially 253 away from the hub 250. As depicted, the holding structures 210 includes eight spokes 252. The number of spokes 252 may vary from those depicted. The hub 250 includes the hole or opening 216 for receiving a mechanical fastener to fasten the modular assembly 208 (and, thus, the flexible loop) to a material substrate layer. In certain embodiments, alternatively or additionally, one or more spokes 252 may include holes or openings 216 (along a long of a respective spoke 252) for receiving respective mechanical fasteners for fastening of the modular assembly 208 to the material substrate layer.

Each spoke 252 includes an end 254 coupled to the hub 250 and an end 256 (e.g., distal end) opposite the end 254. The holding structure 210 is configured to hold the flexible loop 186 while maintaining its looped shape. In particular, the holding structure 210 includes receptacles 214 for receiving the flexible loop 186 and holding the flexible loop 186. As depicted, the receptacles 214 are disposed on a periphery 258 of the holding structure 210. In particular, the receptacles are located on the ends 256 of the spokes 252. The holding structure 210 is configured to maintain a position of the flexible loop 186 on the material substrate layer as the one or more mechanical fasteners is fastened to the holding structure 210 to attach both the holding structure 210 and the flexible loop 186 to the material substrate layer.

The electronics unit 212 is electronically coupled to the flexible loop 186. The electronics unit 212 is also coupled to the holding structure 210 at the end 256 of one of the spokes 252. The electronics unit 212 includes openings or holes 218 for receiving the mechanical fasteners to fasten the electronics unit 212 to the material substrate layer.

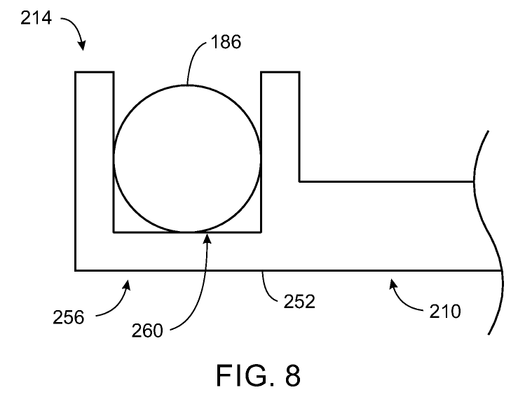

FIG. 8 is a schematic diagram of a portion of the modular assembly 208 coupled to the flexible loop 186 of a radio frequency coil assembly. As depicted, the end 256 of the spoke 252 of the holding structure 210 includes the receptacle 214. The flexible loop 186 is disposed within the receptacle 214. The shape of a bottom portion 260 of the receptacle 214 may vary. As depicted, the bottom portion 260 includes a rectilinear shape. In certain embodiments, the bottom portion 260 may include a curved shape or another shape.

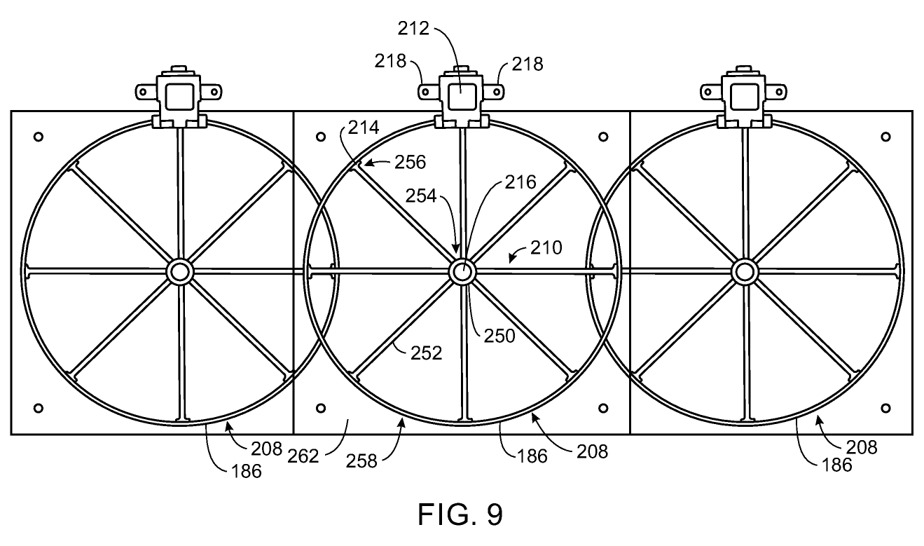

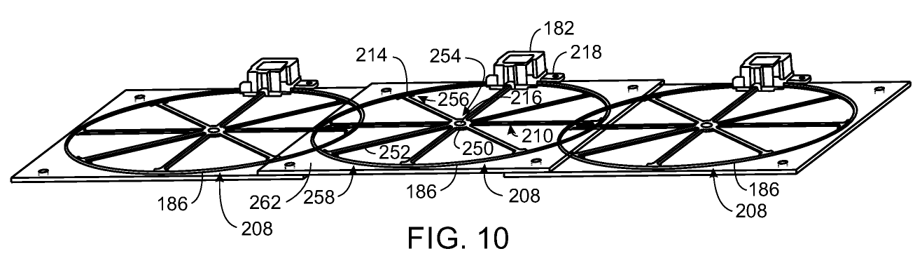

FIGS. 9 and 10 are schematic diagrams of different views of modular assemblies 208 respectively coupled to flexible loops 186 of a radio frequency coil assembly. The modular assemblies 208 are as described in FIG. 7. As depicted, each modular assembly 208 (and its respective flexible loop 186) is coupled to a respective material substrate layer 262 (e.g., respective flexible anchoring material layer). As depicted, the modular assemblies 208 coupled the respective material substrate layers 262 are arranged so that each flexible loop 186 partially overlaps with an adjacent flexible loop 186. For example, the left flexible loop 186 partially overlaps with the central flexible loop 186, the right flexible loop 186 partially overlaps with the central flexible loop 186, and the central flexible loop 186 partially overlaps with both left flexible loop 186 and the right flexible loop 186. In addition, the respective material substrate layers 262 are arranged so that portions of the material substrate layers 262 partially overlap. In certain embodiments, the modular assembly 208 includes multiple holding structures 210 coupled together to enable fastening of multiple respective flexible loops at a time (e.g., and the flexible loops may share a common electronics unit).

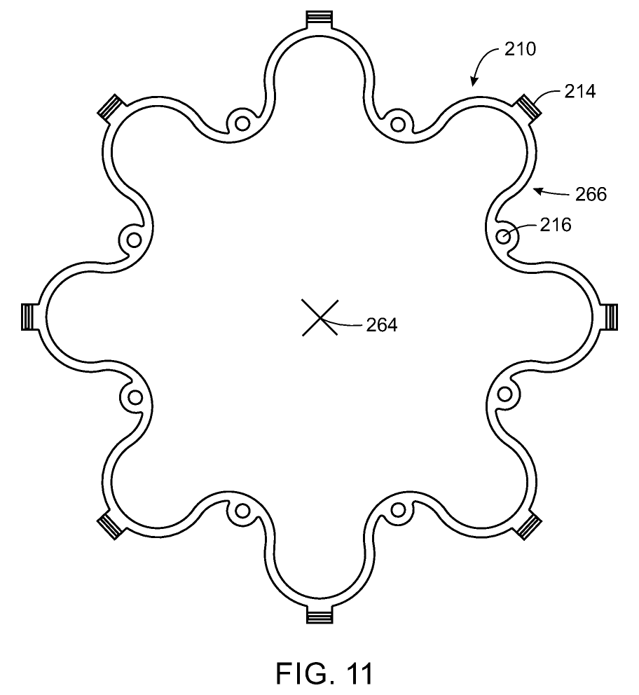

FIG. 11 is a schematic diagram of a top view of the holding structure 210 of a modular assembly having a squiggly shape. The holding structure 210 is made of an MRI compatible material (e.g., non-magnetic metals, polymers, or plastics). The holding structure 210 includes a plurality of holes or openings 216 for receiving respective mechanical fasteners to fasten the modular assembly (and, thus, the flexible loop) to a material substrate layer. As depicted, the holes or openings 216 are off center from a center 264 of the holding structure and disposed along the periphery 266 of the holding structure 210. As depicted, the holding structure 210 includes eight holes or openings 216. The number of holes or openings 216 may vary.

The holding structure 210 is configured to hold the flexible loop while maintaining its looped shape. In particular, the holding structure 210 includes receptacles 214 for receiving the flexible loop and holding the flexible loop. As depicted, the receptacles 214 are disposed on the periphery 266 of the holding structure 210. As depicted, the holding structure 210 includes eight receptacles 214. The number of receptacles 214 may vary. As depicted, the holes or openings 216 and the receptacles 214 are alternately arranged about the periphery. As depicted, the holes or openings 216 are radially disposed closer to the center 264 than the receptacles 214. The holding structure 210 is configured to maintain a position of the flexible loop on the material substrate layer as the one or more mechanical fasteners is fastened to the holding structure 210 to attach both the holding structure 210 and the flexible loop to the material substrate layer.

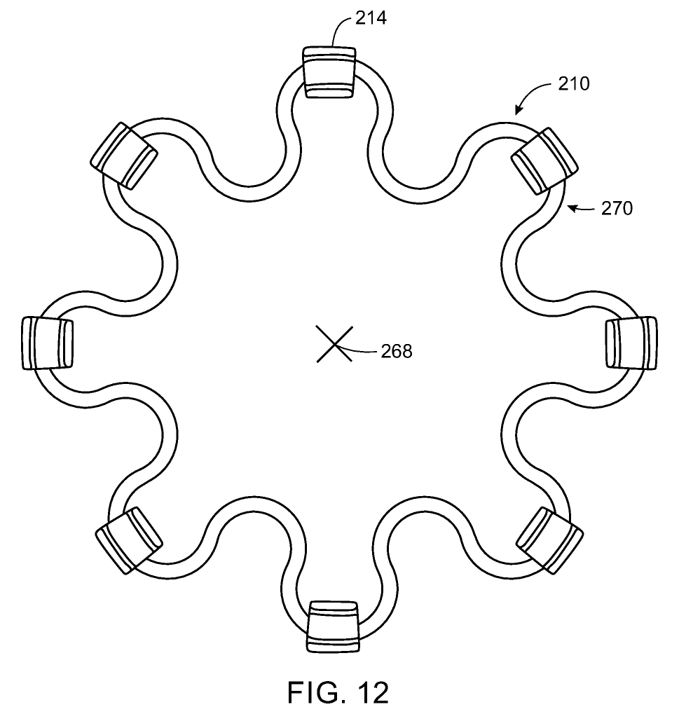

FIG. 12 is a schematic diagram of a top view of a smaller holding structure 210 (relative to the holding structure 210 in FIG. 11) having a squiggly shape. The smaller holding structure 210 is made of an MRI compatible material (e.g., non-magnetic metals, polymers, or plastics). In certain embodiments, the smaller holding structure 210 includes a plurality of holes or openings (similar to those depicted on the holding structure 210 in FIG. 11) for receiving respective mechanical fasteners to fasten the modular assembly (and, thus, the flexible loop) to a material substrate layer. The holes or openings 216 would be off center from a center 268 of the smaller holding structure and disposed along a periphery 270 of the smaller holding structure 210 (similar to those depicted on the holding structure 210 in FIG. 11). The number of holes or openings may vary.

The smaller holding structure 210 is configured to hold the flexible loop while maintaining its looped shape. In particular, the smaller holding structure 210 includes receptacles 214 for receiving the flexible loop and holding the flexible loop. As depicted, the receptacles 214 are disposed on the periphery 270 of the smaller holding structure 210. As depicted, the smaller holding structure 210 includes eight receptacles 214. The number of receptacles 214 may vary. The smaller holding structure 210 is configured to maintain a position of the flexible loop on the material substrate layer as the one or more mechanical fasteners is fastened to the smaller holding structure 210 to attach both the smaller holding structure 210 and the flexible loop to the material substrate layer.

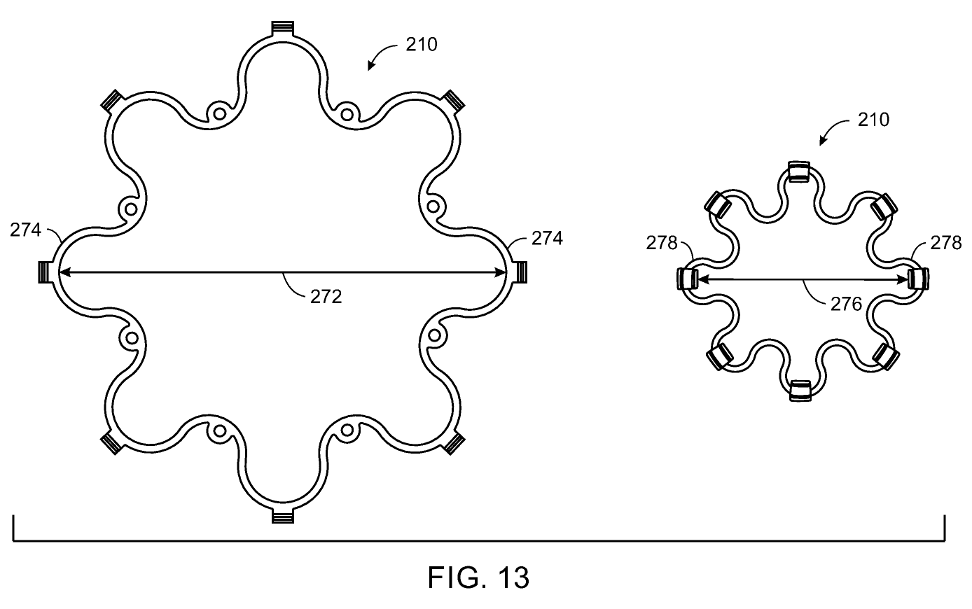

FIG. 13 is a schematic diagram of a top view of the holding structures 210 in FIGS. 11 and 12. On the left of FIG. 13 is the holding structure 210 in FIG. 11. On the right of FIG. 13 is the smaller holding structure 210 in FIG. 12. The holding structure 210 on the left has a distance 272 between opposite ends 274. The smaller holding structure 210 on the right has a distance 276 between opposite ends 278. The distance 272 is larger than the distance 276. It should be noted that the shape of the holding structure 210 may vary from the shapes depicted in holding structures 210 in FIGS. 7 and 9-13.

Technical effects of the disclosed subject matter include providing for modular installation of loops (e.g., elements) of a radio frequency (RF) coil for a magnetic resonance imaging (MRI) system. Technical effects of the disclosed embodiments include providing for the mechanical attachment of the loops of the radio frequency coil to a material substrate layer (e.g., flexible anchoring material layer). Technical effects of the disclosed embodiments include providing a modular design that can replace coil elements in an array by removing the mechanical fasteners that hold the loop in place. Technical effects of the disclosed embodiments include eliminating the sewing of the coil elements and instead providing for the fastening of the loop and electronics onto the fabric directly. Technical effects of the disclosed embodiments include allowing for quicker replacement and assembly than the current techniques. The disclosed embodiments provide a more reliable manufacturing method. Technical effects of the disclosed embodiments include reducing cost and providing a more modular design. Technical effects of the disclosed embodiments include reducing manufacturing time. Technical effects of the disclosed embodiments include reducing the number of failures seen and improve repair times on the radio frequency receiving coil assembly.

The disclosure also provides support for a radio frequency receiving coil assembly for a magnetic resonance imaging system, comprising: a flexible enclosure; and a radio frequency coil disposed within the flexible enclosure, wherein the radio frequency coil comprises a plurality of flexible loops having a malleable conductor, wherein each flexible loop of the plurality of flexible loops is fastened to a material substrate layer disposed within the flexible enclosure via a modular assembly comprising a holding structure holding a respective flexible loop and one or more mechanical fasteners attaching both the holding structure and the respective flexible loop to the material substrate layer. In a first example of the radio frequency receiving coil assembly, the holding structure is configured to maintain a position of the respective flexible loop on the material substrate layer as the one or more mechanical fasteners is fastened to the holding structure to attach both the holding structure and the respective flexible loop to the material substrate layer. In a second example of the radio frequency receiving coil assembly, optionally including the first example, the modular assembly further comprises an electronics unit electronically coupled to the respective flexible loop and coupled to the holding structure that is fastened via one or more mechanical fasteners to the material substrate layer. In a third example of the radio frequency receiving coil assembly, optionally include one or both of the first and second examples, the holding structure comprises a hub and a plurality of spokes radially extending from the hub. In a fourth example of the radio frequency receiving coil assembly, optionally including one or more or each of the first through third examples, respective ends of the plurality of spokes disposed away from the hub comprise receptacles for receiving the respective flexible loop and holding the respective flexible loop in the position on the material substrate layer prior to and subsequent to attachment to the material substrate layer. In a fifth example of the radio frequency receiving coil assembly, optionally including one or more or each of the first through fourth examples, a mechanical fastener of the one or more mechanical fasteners is fastened to the hub to attach both the holding structure and the respective flexible loop to the material substrate layer. In a sixth example of the radio frequency receiving coil assembly, optionally including one or more or each of the first through fifth examples, the holding structure comprises one or more holes within it that are off center from a center of the holding structure, and the one or more mechanical fasteners are disposed within the holes to attach both the holding structure and the respective flexible loop to the material substrate layer. In a seventh example of the radio frequency receiving coil assembly, optionally including one or more or each of the first through sixth examples, the modular assembly is configured to enable removal of the respective flexible loop for replacement via the removal of the one or more mechanical fasteners to detach the respective flexible loop from the material substrate layer.

The disclosure also provides support for a modular assembly for assembling a radio frequency receiving coil assembly for a magnetic imaging system, comprising: a holding structure configured to hold a flexible loop of the radio frequency receiving coil assembly, wherein the flexible loop has a malleable conductor; an electronics unit coupled to the holding structure; and mechanical fasteners configured to attach the electronics unit, the holding structure, and the flexible loop to a material substrate layer configured to be disposed within a flexible enclosure, wherein the holding structure is configured to maintain a position of the flexible loop on the material substrate layer as the one or more mechanical fasteners is fastened to the holding structure to attach both the holding structure and the respective loop to the material substrate layer. In a first example of the modular assembly, the holding structure comprises a hub and a plurality of spokes radially extending from the hub. In a second example of the modular assembly, optionally including the first example, respective ends of the plurality of spokes disposed away from the hub comprise receptacles for receiving the flexible loop and holding the flexible loop in the position on the material substrate layer prior to and subsequent to attachment to the material substrate layer. In a third example of the modular assembly, optionally including the one or both of the first and second examples, a mechanical fastener of the one or more mechanical fasteners is fastened to the holding structure to attach both the holding structure and the flexible loop to the material substrate layer. In a fourth example of the modular assembly, optionally including one or more or each of the first through third examples, the holding structure comprises one or more holes within it that are off center from a center of the holding structure, and the one or more mechanical fasteners are disposed within the holes to attach both the holding structure and the flexible loop to the material substrate layer. In a fifth example of the modular assembly, optionally including one or more or each of the first through fourth examples, the modular assembly is configured to enable removal of the flexible loop for replacement via the removal of the one or more mechanical fasteners to detach both the respective flexible loop and the electronics unit from the material substrate layer.

The disclosure also provides support for a method for modular assembly and repair of a radio frequency coil for a magnetic imaging system, comprising: providing a material substrate layer; placing a modular assembly comprising a holding structure holding a flexible loop of the radio frequency coil on the material substrate layer, wherein the flexible loop has a malleable conductor; aligning the holding structure and the flexible loop to a position on the material substrate layer; and fastening the holding structure and the flexible loop to the material substrate layer. In a first example of the method, the holding structure is configured to maintain a position of the flexible loop on the material substrate layer as the one or more mechanical fasteners is fastened to the holding structure to attach both the holding structure and the flexible loop to the material substrate layer. In a second example of the method, optionally including the first example, the modular assembly comprises an electronics unit electrically coupled to the flexible loop and coupled to the holding structure, wherein the method further comprises attaching the electronics unit to the material substrate layer via one or more additional mechanical fasteners. In a third example of the method, optionally including one or both of the first and second examples, the method comprises detaching the one or more mechanical fasteners and the one or more additional mechanical fasteners; removing the flexible loop associated with the modular assembly; coupling the modular assembly to a replacement flexible loop of the radio frequency coil; placing the modular assembly with the replacement flexible loop of the radio frequency coil on the material substrate layer; aligning the holding structure and the replacement flexible loop to the position on the material substrate layer; and fastening the electronics unit, the holding structure, and the replacement flexible loop to the material substrate layer. In a fourth example of the method, optionally including one or more or each of the first through third examples, the method comprises disposing the material substrate layer with the modular assembly and the flexible loop fastened to the material subject layer into a flexible enclosure. In a fifth example of the method, optionally including one or more or each of the first through fourth examples, the holding structure comprises receptacles for receiving the flexible loop and holding the flexible loop in the position on the material substrate layer prior to and subsequent to attachment to the material substrate layer.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more coil elements designated as “means for [perform]ing [a function]…” or “step for [perform]ing [a function]…”, it is intended that such coil elements are to be interpreted under 35 U.S.C. 112(f). However, for any claims containing coil elements designated in any other manner, it is intended that such coil elements are not to be interpreted under 35 U.S.C. 112(f).

This written description uses examples to disclose the present subject matter, including the best mode, and also to enable any person skilled in the art to practice the subject matter, including making and using any devices or systems and performing any incorporated methods. The patentable scope of the subject matter is defined by the claims, and may include other examples that occur to those skilled in the art. Such other examples are intended to be within the scope of the claims if they have structural coil elements that do not differ from the literal language of the claims, or if they include equivalent structural coil elements with insubstantial differences from the literal languages of the claims.

1. A radio frequency receiving coil assembly for a magnetic resonance imaging system, comprising:
a flexible enclosure; and
a radio frequency coil disposed within the flexible enclosure, wherein the radio frequency coil comprises a plurality of flexible loops having a malleable conductor, wherein each flexible loop of the plurality of flexible loops is fastened to a material substrate layer disposed within the flexible enclosure via a modular assembly comprising a holding structure holding a respective flexible loop and one or more mechanical fasteners attaching both the holding structure and the respective flexible loop to the material substrate layer.

2. The radio frequency receiving coil assembly of claim 1, wherein the holding structure is configured to maintain a position of the respective flexible loop on the material substrate layer as the one or more mechanical fasteners is fastened to the holding structure to attach both the holding structure and the respective flexible loop to the material substrate layer.

3. The radio frequency receiving coil assembly of claim 2, wherein the modular assembly further comprises an electronics unit electronically coupled to the respective flexible loop and coupled to the holding structure that is fastened via one or more mechanical fasteners to the material substrate layer.

4. The radio frequency receiving coil assembly of claim 2, wherein the holding structure comprises a hub and a plurality of spokes radially extending from the hub.

5. The radio frequency receiving coil assembly of claim 4, wherein respective ends of the plurality of spokes disposed away from the hub comprise receptacles for receiving the respective flexible loop and holding the respective flexible loop in the position on the material substrate layer prior to and subsequent to attachment to the material substrate layer.

6. The radio frequency receiving coil assembly of claim 5, wherein a mechanical fastener of the one or more mechanical fasteners is fastened to the hub to attach both the holding structure and the respective flexible loop to the material substrate layer.

7. The radio frequency receiving coil assembly of claim 2, wherein the holding structure comprises one or more holes within it that are off center from a center of the holding structure, and the one or more mechanical fasteners are disposed within the holes to attach both the holding structure and the respective flexible loop to the material substrate layer.

8. The radio frequency receiving coil assembly of claim 2, wherein the modular assembly is configured to enable removal of the respective flexible loop for replacement via the removal of the one or more mechanical fasteners to detach the respective flexible loop from the material substrate layer.

9. A modular assembly for assembling a radio frequency receiving coil assembly for a magnetic imaging system, comprising:
a holding structure configured to hold a flexible loop of the radio frequency receiving coil assembly, wherein the flexible loop has a malleable conductor;
an electronics unit coupled to the holding structure; and
mechanical fasteners configured to attach the electronics unit, the holding structure, and the flexible loop to a material substrate layer configured to be disposed within a flexible enclosure, wherein the holding structure is configured to maintain a position of the flexible loop on the material substrate layer as the one or more mechanical fasteners is fastened to the holding structure to attach both the holding structure and the respective loop to the material substrate layer.

10. The modular assembly of claim 9, wherein the holding structure comprises a hub and a plurality of spokes radially extending from the hub.

11. The modular assembly of claim 10, wherein respective ends of the plurality of spokes disposed away from the hub comprise receptacles for receiving the flexible loop and holding the flexible loop in the position on the material substrate layer prior to and subsequent to attachment to the material substrate layer.

12. The modular assembly of claim 11, wherein a mechanical fastener of the one or more mechanical fasteners is fastened to the holding structure to attach both the holding structure and the flexible loop to the material substrate layer.

13. The modular assembly of claim 9, wherein the holding structure comprises one or more holes within it that are off center from a center of the holding structure, and the one or more mechanical fasteners are disposed within the holes to attach both the holding structure and the flexible loop to the material substrate layer.

14. The modular assembly of claim 9, wherein the modular assembly is configured to enable removal of the flexible loop for replacement via the removal of the one or more mechanical fasteners to detach both the respective flexible loop and the electronics unit from the material substrate layer.

15. A method for modular assembly and repair of a radio frequency coil for a magnetic imaging system, comprising:
providing a material substrate layer;
placing a modular assembly comprising a holding structure holding a flexible loop of the radio frequency coil on the material substrate layer, wherein the flexible loop has a malleable conductor;
aligning the holding structure and the flexible loop to a position on the material substrate layer; and
fastening the holding structure and the flexible loop to the material substrate layer.

16. The method of claim 15, wherein the holding structure is configured to maintain a position of the flexible loop on the material substrate layer as the one or more mechanical fasteners is fastened to the holding structure to attach both the holding structure and the flexible loop to the material substrate layer.

17. The method of claim 16, wherein the modular assembly comprises an electronics unit electrically coupled to the flexible loop and coupled to the holding structure, wherein the method further comprises attaching the electronics unit to the material substrate layer via one or more additional mechanical fasteners.

18. The method of claim 17, further comprising:
detaching the one or more mechanical fasteners and the one or more additional mechanical fasteners;
removing the flexible loop associated with the modular assembly;
coupling the modular assembly to a replacement flexible loop of the radio frequency coil;
placing the modular assembly with the replacement flexible loop of the radio frequency coil on the material substrate layer;
aligning the holding structure and the replacement flexible loop to the position on the material substrate layer; and
fastening the electronics unit, the holding structure, and the replacement flexible loop to the material substrate layer.

19. The method of claim 16, further comprising disposing the material substrate layer with the modular assembly and the flexible loop fastened to the material subject layer into a flexible enclosure.

20. The method of claim 16, wherein the holding structure comprises receptacles for receiving the flexible loop and holding the flexible loop in the position on the material substrate layer prior to and subsequent to attachment to the material substrate layer.
